(19) United States
(12) Patent Application Publication
(10) Pub. No.: US 2023/0091551 A1
(43) Pub. Date: Mar. 23, 2023

(54) WHITE ORGANIC LIGHT EMITTING DEVICE WITH STABLE SPECTRUM EMPLOYING TRANSPORT BARRIER LAYERS

(71) Applicant: The Regents of the University of Michigan, Ann Arbor, MI (US)

(72) Inventors: Boning Qu, Ann Arbor, MI (US); Stephen R. FORREST, Ann Arbor, MI (US)

(21) Appl. No.: 17/934,388

(22) Filed: Sep. 22, 2022

Related U.S. Application Data
(60) Provisional application No. 63/247,485, filed on Sep. 23, 2021.

(51) Int. Cl. H01L 51/50

(52) U.S. Cl. CPC H01L 51/5096; H01L 51/5004; H01L 2251/558

(57) ABSTRACT

An organic light emitting device comprises an anode, a first hole transport layer positioned over the anode, a barrier transport layer positioned over the first hole transport layer, a second hole transport layer positioned over the barrier transport layer, at least one emissive layer positioned over the second hole transport layer, and a cathode positioned over the at least one emissive layer.

### CROSS-REFERENCE TO RELATED APPLICATIONS

This application claims priority to U.S. provisional application No. 63/247,485 filed on Sep. 23, 2021, incorporated herein by reference in its entirety.

### STATEMENT REGARDING FEDERALLY SPONSORED RESEARCH OR DEVELOPMENT

This invention was made with government support under DE-EE0008723 awarded by the U.S. Department of Energy. The government has certain rights in the invention.

### BACKGROUND OF THE INVENTION

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety. One application for phosphorescent emissive molecules is a full color display. Industry standards for such a display call for pixels adapted to emit particular colors, referred to as “saturated” colors. In particular, these standards call for saturated red, green, and blue pixels. Color may be measured using CIE coordinates, which are well known to the art.

One example of a green emissive molecule is tris(2-phenylpyridine) iridium, denoted Ir(ppy)₃, which has the following structure:

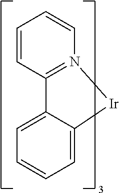

In this, and later figures herein, we depict the dative bond from nitrogen to metal (here, Ir) as a straight line.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, on a conventional energy level diagram, with the vacuum level at the top, a “shallower” energy level appears higher, or closer to the top, of such a diagram than a “deeper” energy level, which appears lower, or closer to the bottom.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

More details on OLEDs, and the definitions described above, can be found in U.S. Pat. No. 7,279,704, which is incorporated herein by reference in its entirety.

Phosphorescent white organic light emitting devices (WOLEDs) are attractive solid state lighting sources due to their high-power efficiency, tunable spectrum, and potentially long lifetime. White light emission can be obtained from multilayer WOLED structures, in which different layers emit different parts of the visible spectrum. However, the color spectrum of WOLEDs often changes with the operating current density because exciton formation zone shifts in emission layers when the injected charges are not balanced. Excitation of phosphors occurs via charge trapping: holes are transported on the phosphors, electrons on the EML host that ultimately transfer to the phosphors as well.

There is a need in the art for a WOLED structure employing a hole transport barrier layer that impedes the hole conduction and improves the charge balance. The present invention satisfies that need; this design reduces the WOLED spectrum color change at different operating current densities and potentially increases WOLED lifetime without decreasing quantum efficiency.

### SUMMARY OF THE INVENTION

In one aspect, an organic light emitting device comprises an anode, a first hole transport layer positioned over the anode, a barrier transport layer positioned over the first hole transport layer, a second hole transport layer positioned over the barrier transport layer, at least one emissive layer positioned over the second hole transport layer, and a cathode positioned over the at least one emissive layer. In one embodiment, the barrier transport layer is positioned in direct contact with the first and second hole transport layers.

In one embodiment, the first and second hole transport layers have the same composition. In one embodiment, the first hole transport layer comprises a material not present in the second hole transport layer. In one embodiment, the barrier transport layer comprises a hole blocking material with a highest occupied molecular orbital energy that is lower than the that of a material included in the first and second hole transport layers. In one embodiment, the hole blocking material possesses high carrier mobilities. In one embodiment, the barrier transport layer is configured to reduce a shift of a location of exciton formation with changes in current.

In one embodiment, the at least one emissive layer comprises a plurality of emissive layers. In one embodiment, the device is configured to emit white light. In one embodiment, the emissive layer has a thickness between 5 nm and 100 nm. In one embodiment, the device further comprises an electron transport layer positioned between the cathode and the emissive layer. In one embodiment, the electron transport layer comprises at least first and second electron transport sublayers, wherein the first electron transport sublayer comprises a material different from the second electron transport sublayer.

In one aspect, an organic light emitting device comprises an anode and a cathode, an emissive layer having an anode-facing surface and a cathode-facing surface, positioned between the anode and the cathode, a first hole transport layer positioned between the anode and the emissive layer, and a barrier transport layer positioned between the anode and the emissive layer, at a distance from the anode-facing surface of the emissive layer of between 1 nm and 50 nm.

In one embodiment, the device further comprises a second hole transport layer positioned between the anode and the emissive layer. In one embodiment, the barrier transport layer is positioned between the first and second hole transport layers. In one embodiment, the barrier transport layer is positioned between the anode and the emissive layer at a distance from the anode-facing surface of the emissive layer of between 1 nm and 10 nm. In one embodiment, the device further comprises an electron transport layer positioned between the emissive layer and the cathode.

In one embodiment, the electron transport layer comprises at least a first electron transport sublayer and a second electron transport sublayer having a material different from the first electron transport sublayer. In one embodiment, emissive layer comprises a plurality of emissive sublayers. In one embodiment, the plurality of emissive sublayers comprise red, green, and blue sublayers.

### BRIEF DESCRIPTION OF THE DRAWINGS

The foregoing purposes and features, as well as other purposes and features, will become apparent with reference to the description and accompanying figures below, which are included to provide an understanding of the invention and constitute a part of the specification, in which like numerals represent like elements, and in which:

FIG. 1 is an exemplary OLED.

FIG. 2 is an exemplary OLED.

FIG. 3A shows structures of WOLEDs W1-W4 comprising three-color emission zones, wherein devices W2 and W4 contain a 5-nanometer thick N,N-dicarbazolyl-3,5-benzene (mCBP) or 4,4-N,N-dicarbazolebiphenyl (CBP) barrier transport layer, respectively.

FIG. 3B exemplifies the energy level diagram for organic materials used in the WOLEDs. Highest occupied molecular orbital (HOMO) and lowest unoccupied molecular orbital (LUMO) energies are labeled in eV.

FIG. 4A illustrates a normalized emission spectra and color shifts (ΔCIE) of devices W1-W4 from 1 to 100 mA/cm².

FIG. 4B shows the color coordinates of devices W1-W4 from 1 to 100 mA/cm² (arrow direction) in the CIE 1931 chromaticity diagram.

FIG. 5A exemplifies the current density-voltage-luminance (j-V-L) characteristics of devices W1-W4.

FIG. 5B illustrates the current density-external quantum efficiency (j-EQE) characteristics of devices in (a).

FIG. 6A and FIG. 6B show various exemplary device structures as contemplated herein.

FIG. 7A is a normalized emission spectra and ΔCIE of devices RG1-RG3 from 1 to 100 mA/cm².

FIG. 7B shows the density-voltage (j-V) of devices RG1-RG3 from 1 to 100 mA/cm².

FIG. 7C exemplifies the density-external quantum efficiency (j-EQE) characteristics of devices in (a). The thicknesses of CBP in devices RG1-3 are 0, 5, 10 nm, respectively.

FIG. 8 illustrates a simulated electron and hole densities for device G1, and G3 at 0.1 and 100 mA/cm². The position x=0 nm corresponds to the EML/HTL interface. The EML is located between x=0 and 30 nm. The ETL layer is located at x>30 nm. The neat CBP BTL is located between x=−15 and −5 nm in G3.

FIG. 9 shows the normalized exciton density distribution in a 30 nm thick EML derived from PQIr sensor emission measurement (data points) and numerical model calculation (lines) for j from 0.1 to 100 mA/cm². Error bars in the sensor emission measurement represent variation from 4 devices and error in deconvolution of the Irppy₃ and PQIr spectra in graph 901; an emission spectra of device G1 with sensors embedded between x=−7.5 nm to 30 nm with 7.5 nm spacings, at a current density of 10 mA/cm² in graph 902, the emission peaks at 520 nm and 594 nm correspond to Ir(ppy)₃ and PQIr emission, respectively; and a simulated exciton density profile in EMLs for device G3 at j=0.1 and 100 mA/c·m² in graph 903.

### DETAILED DESCRIPTION OF THE INVENTION

It is to be understood that the figures and descriptions of the present invention have been simplified to illustrate elements that are relevant for a clearer comprehension of the present invention, while eliminating, for the purpose of clarity, many other elements found in systems and methods of a white organic light emitting device with stable spectrum employing transport barrier layers. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, the preferred methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, and ±0.1% from the specified value, as such variations are appropriate.

Ranges: throughout this disclosure, various aspects of the invention can be presented in a range format. It should be understood that the description in range format is merely for convenience and brevity and should not be construed as an inflexible limitation on the scope of the invention. Where appropriate, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, and 6. This applies regardless of the breadth of the range.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), which are incorporated by reference in their entireties. Phosphorescence is described in more detail in U.S. Pat. No. 7,279,704 at cols. 5-6, which are incorporated by reference.

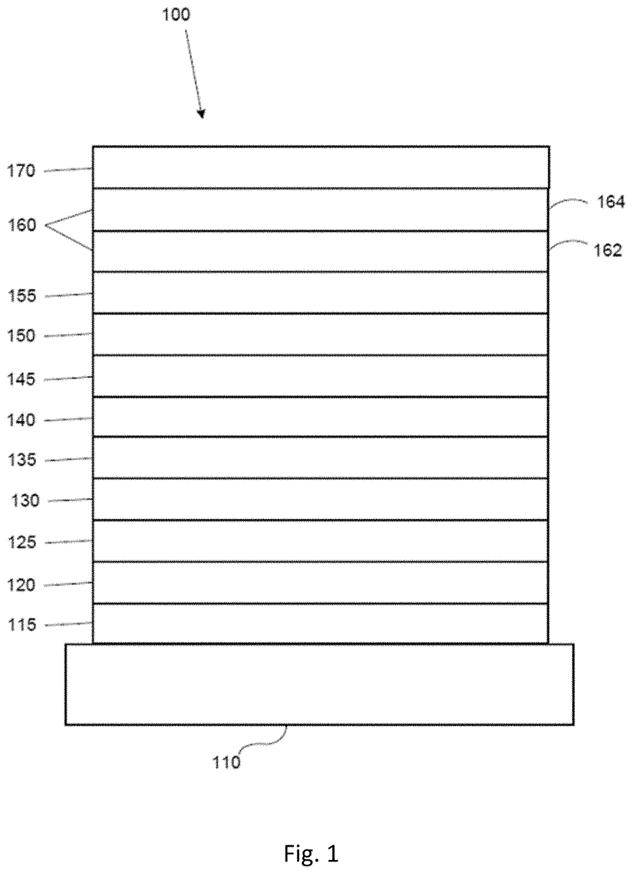

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

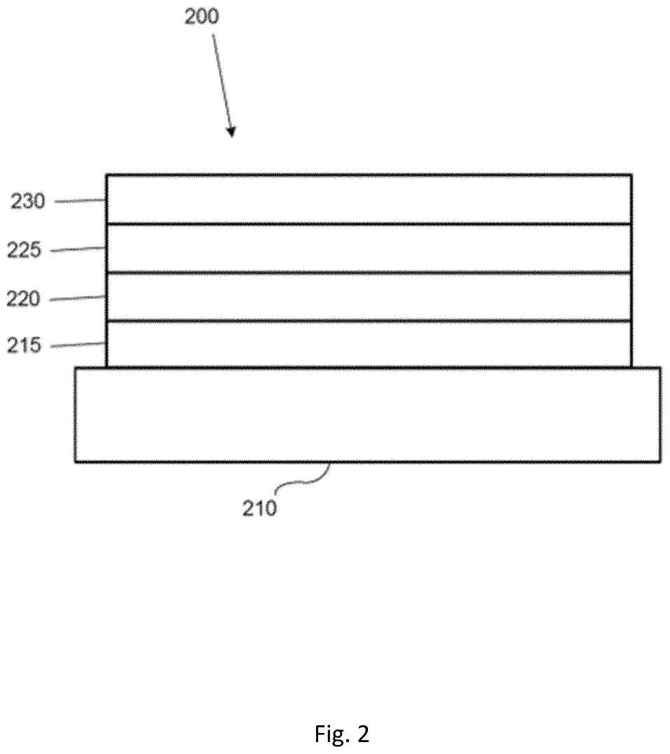

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the disclosure may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve outcoupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processability than those having symmetric structures, because asymmetric materials may have a lower tendency to recrystallize. Dendrimer substituents may be used to enhance the ability of small molecules to undergo solution processing.

Devices fabricated in accordance with embodiments of the present disclosure may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the disclosure can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the disclosure can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include flat panel displays, curved displays, computer monitors, medical monitors, televisions, billboards, lights for interior or exterior illumination and/or signaling, heads-up displays, fully or partially transparent displays, flexible displays, rollable displays, foldable displays, stretchable displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays tiled together, theaters or stadium screens, light therapy devices, and signs. Various control mechanisms may be used to control devices fabricated in accordance with the present disclosure, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

Although certain embodiments of the disclosure are discussed in relation to one particular device or type of device (for example OLEDs) it is understood that the disclosed improvements to light outcoupling properties of a substrate may be equally applied to other devices, including but not limited to PLEDs, OPVs, charge-coupled devices (CCDs), photosensors, or the like.

Although exemplary embodiments described herein may be presented as methods for producing particular circuits or devices, for example OLEDs, it is understood that the materials and structures described herein may have applications in devices other than OLEDs. For example, other optoelectronic devices such as organic solar cells and organic photodetectors may employ the materials and structures. More generally, organic devices, such as organic transistors, or other organic electronic circuits or components, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, wherein the emitter material has a total non-radiative decay rate constant and a total radiative decay rate constant due to the presence of the enhancement layer and the threshold distance is where the total non-radiative decay rate constant is equal to the total radiative decay rate constant. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters the energy from the surface plasmon polaritons. In some embodiments this energy is scattered as photons to free space. In other embodiments, the energy is scattered from the surface plasmon mode into other modes of the device such as but not limited to the organic waveguide mode, the substrate mode, or another waveguiding mode. If energy is scattered to the non-free space mode of the OLED other outcoupling schemes could be incorporated to extract that energy to free space. In some embodiments, one or more intervening layer can be disposed between the enhancement layer and the outcoupling layer. The examples for interventing layer(s) can be dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a plurality of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

WOLEDs for general lighting require stable spectra that are largely independent of brightness. Described herein, the phosphorescent WOLED spectra are stabilized using a barrier transport layer (BTL) inserted between two hole transport layers. As used herein, a barrier transport layer refers to a hole blocking layer positioned on the anode side of the emissive layer, adjacent to or between one or more hole transport layers.

The spectral improvement induced by the BTL is investigated in three-color WOLEDs and two-color OLEDs. For a WOLED with a peak external quantum efficiency of 15±1% at 0.1 mA/cm², the color difference (ΔEab*) in the CIELab 1976 color space is noticeably reduced from 12.8±0.2 to 8.6±0.1 as the current density is increased from 1 to 100 mA/cm². A numerical model is derived to systematically understand the role of charge blocking in tailoring the exciton distribution in the complex WOLED layer structure. The model is validated by direct measurements of the exciton distribution within an OLED emission layer. The color shift with current in conventional WOLEDs is attributed to unbalanced charge injection due to asymmetrical energy barriers for electrons and holes between the emission layer and the surrounding transport and injection layers. Addition of a barrier transport layer balances the charge conduction, generates a uniform exciton profile, and reduces the spectral shift.

Phosphorescent white organic light emitting diodes (WOLEDs) are promising solid state lighting sources given their high-power efficiencies, color rendering indexes (CRI) and long operating lifetimes (Coburn, C., et al, ACS Photonics 2018, 5, 630-635. Kato, K., et al., J. Photopolym. Sci. Technol. 2015, 28 (3), 335-340. Qu, B., et al., ACS Nano 2020, 14 (10), 14157-14163. Sasabe, H. and Kido, J., J. Mater. Chem. C 2013, 1 (9), 1699-1707.) White light emission is typically obtained by combining several emitting organic molecules that span the visible spectrum. Often, WOLEDs rely on arranging multiple color emitting elements within a united emitting layer (EML).

However, this deceptively simple architecture can exhibit unwanted intensity-dependent color-shifts (Andrade, B. B. W. D. and Thompson, M. E., Adv. Mater. 2002, 2, 147; Sun, Y., et al., Nature 2006, 440, 908; Zhao, C., et al., J. Mater. Chem. C 2018, 6 (35), 9510-9516. Sun, Q., et al., Appl. Phys. Lett. 2008, 92 (25), 251108). Progress has been made in realizing stable white spectra by using additional chromatic layers to enhance the color balance, or transport layers in the middle of the emission zone to alter the charge balance (Li, J., et al., J. Phys. D. Appl. Phys. 2021, 54 (16), 165105; Gather, M. C., et al., Adv. Mater. 2007, 19 (24), 4460-4465; Wang, Q., et al., J. Phys. D. Appl. Phys. 2013, 46 (15), 155102; Yang, F., et al., Opt. Mater. (Amst). 2018, 82, 130-134). These interlayers adjust the charge transport by introducing energy barriers or low mobility regions within, or directly adjacent to the EMLs, and can sometimes improve device efficiency (Wang, Q., et al., J. Phys. D. Appl. Phys. 2013, 46 (15), 155102; Loeser, F., et al., J. Photonics Energy. 2012, 2, 021207). However, such interlayers add fabrication complexity when they are used in high quality lighting sources, whose EML consists of at least three color elements to generate the full spectrum. Reliable transport materials with energy levels compatible with all EML elements are also limited. Moreover, it can be challenging to predict the exciton distribution across broad emission zones common to WOLEDs, making their optimal design accessible only through the fabrication and measurement of numerous, complex designs that iterate through different materials, layer thicknesses and their positions within the device stack.

The invention described herein is focused on stabilizing the WOLED spectrum using a single charge blocking layer that is external to the three-color EML, and the effects that charge balance has on determining the location of exciton formation are investigated. The charge distribution and balance is studied through the fabrication of single carrier devices combined with a charge drift-diffusion model that accurately simulates the exciton recombination dynamics within the layers, and across the interfaces (Altazin, S., et al., J. Appl. Phys. 2018, 124 (13), 135501; Ruhstaller, B., et al., J. Appl. Phys. 2001, 89, 4575; Arkhipov, V. I., et al., J. Appl. Phys. 2001, 90, 2352; Lu, F., et al., J. Semicond. 2014, 35, 044005.) Simulation results were verified by direct measurements of the exciton distribution in multilayer OLEDs (Staudigel, J., et al., J. Appl. Phys. 1999, 86 (7), 3895-3910).

Specifically, WOLEDs employing three phosphorescent emitters in the red, green and blue, are fabricated. The spectral change with current originates from the shift of the exciton formation zone between different doped layers within the EML. Inserting materials to create energy barriers within the hole transport layers (HTLs) balances the charge transport and reduces the shift of the location of exciton formation with current. Including a barrier transport layer (BTL) within the HTL noticeably stabilizes the WOLED Commission Internationale de L'Eclairage (CIE) 1931 chromaticity coordinate drift (ΔCIE) from (0.032, 0.025) to (0.021, 0.017) as the current density is increased from 1 to 100 mA/cm², whereas the peak external quantum efficiency of EQE=15±1% is unchanged. The associated color difference (ΔEab*) in CIELab 1976 color space is reduced from 12.8±0.2 to 8.6±0.1.

Described herein is a WOLED structure wherein a barrier transport layer (BTL) is inserted at the interface between the hole transport layer (HTL) and the EML, or in the middle of the HTL to intentionally introduce an energy barrier in hole conduction. The BTL materials possess high carrier mobilities and HOMOs that are lower than both the adjacent or surrounding HTLs and dopants in EMLs. Exemplary advantages of employing a BTL in WOLEDs include, 1. balancing the hole and electron charge population in EMLs at different applied voltages by forcing the hole conduction regime to be similar to electron conduction, 2. reducing the spectrum color change and retaining high CRI at different operating current densities, and 3. potentially increasing WOLED lifetime by avoiding unnecessary high energy triplet formation due to shifts in the excition formation zone. Furthermore, since BTLs do not interfere with EMLs or decrease WOLED quantum efficiencies, this architecture can be applied to previously existing WOLED designs.

### Theory

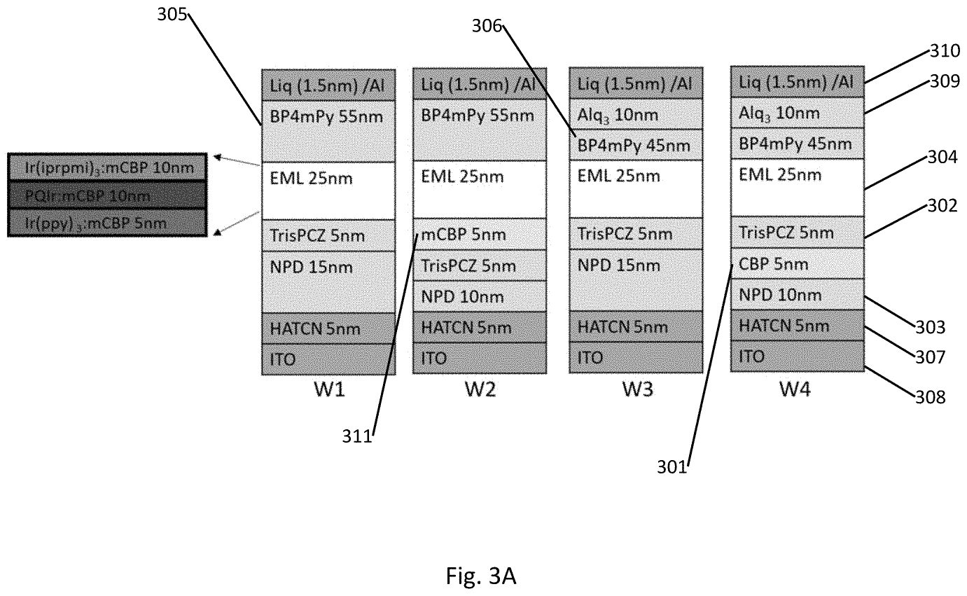

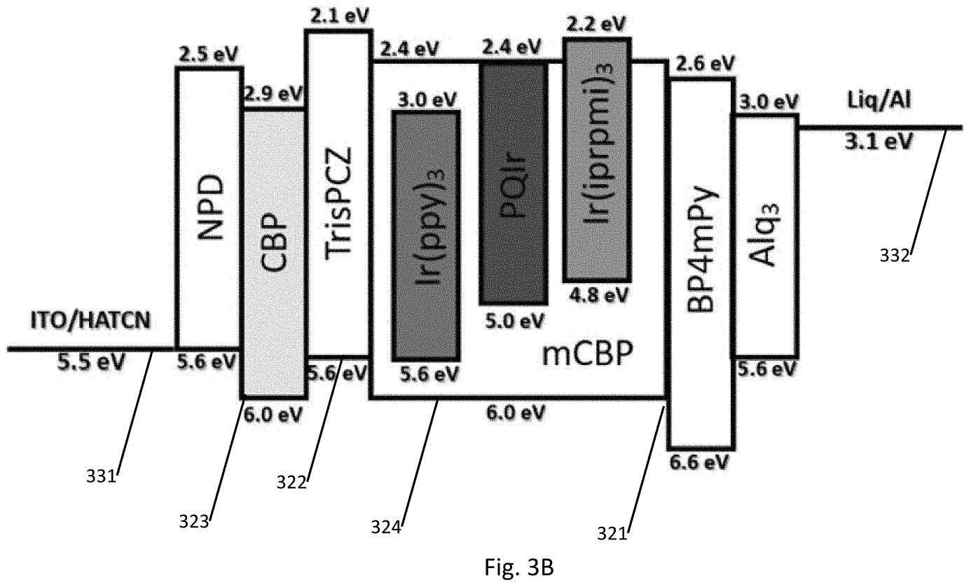

Conventional multilayer WOLED structures consist of electrodes, hole/electron injection layers (H/EILs), hole/electron transport layers (H/ETLs), and EMLs made of multiple sub-layers for emitting light in different parts of the spectrum. The WOLED employing a BTL is shown in FIG. 3A. In the exemplary device labeled W4, the BTL 301 is placed in between two HTLs 302 and 303, and outside of EML 304. HTL 302 can be made of the same materials as HTL 303, for example materials with shallow LUMO to block electrons from the ETL 305 (which may also function as an HBL), or may in some embodiments be made from the same materials. In some embodiments, one or both of HTL 302 or HTL 303 are omitted. In some embodiments, as shown in device W2, an HTL may comprise multiple sublayers having different materials, with a BTL 311 positioned between the sublayers and the EML.

Example devices W1, W2, W3, and W4 shown in FIG. 3A are not meant to be limiting, and merely present exemplary configurations of devices contemplated herein. As would be understood by one skilled in the art, the emissive layer 304 could comprise a single emissive layer or a plurality of emissive sublayers, each having the same or a different color from the other emissive sublayers in the stack. The depicted examples of FIG. 3A comprise three emissive sublayers, a 10 nm blue sublayer (top) a 10 nm red sublayer (middle) and a 5 nm green sublayer (bottom). The emissive layer 304 could have a total thickness between 5 nm and 100 nm, or between 5 nm and 70 nm, or between 5 nm and 50 nm, or between 10 nm and 30 nm, or about 25 nm.

In various configurations, a device as contemplated herein could include a barrier transport layer (BTL) positioned between the emissive layer and the hole transport layer (as shown in device W2) or between two hole transport layers each comprising the same or a different hole transport material, as shown in device W4. The BTL could be positioned at a distance from the nearest surface of the emissive layer of about 5 nm, as shown in device W4, or between 1 nm and 50 nm, or between 1 nm and 40 nm, or between 1 nm and 30 nm, or between 1 nm and 20 nm, or between 1 nm and 10 nm, or between 1 nm and 5 nm, or at a distance of less than 50 nm, less than 40 nm, less than 30 nm, less than 20 nm, less than 10 nm, or less than 5 nm. In some embodiments, a distance between the BTL and the nearest surface of the EML may vary across the surface area of the device.

The depicted devices all additionally include a hole injection layer 307, which in the depicted example comprises HATCN, an ITO anode 308, and a 1.5 nm thick Liq electron injection layer (on the bottom surface of Aluminum cathode 310). Devices W3 and W4 include a different electron transport layer comprising two sublayers of different materials, the first sublayer 306 as a 45 nm thick BP4mPy, and the second sublayer 309 as a 10 nm thick Alq₃ sublayer.

The schematic energy levels of the layers involved in the WOLED design are shown in FIG. 3B. For barrier-free hole conduction in conventional WOLEDs (see FIG. 3A), the space charge limited hole current is proportional to the square of voltage drop across the EML. For injection or trap-limited electron conduction, current changes with a much higher order of voltage or even exponentially with voltage. At low voltage, charges recombine primarily near the EML/ETL interface 321, where electrons are limited by the LUMO barrier, yet holes are abundant. At high voltage, electron current increases faster and overwhelms the hole current, which causes the exciton formation zone to shift towards the HTL 322, which may also function as an electron blocking layer.

In WOLEDs employing BTLs, the hole current is impeded by the transport barrier 323 and increases at a comparable rate as the electron current with voltages so that the exciton formation zone does not shift within the EML.

Charges injected from the electrodes 331 and 332 are transported into the EML 324 where they eventually recombine to form excitons, or are transported into adjacent layers to nonradiatively recombine. Charge drift-diffusion with thermionic emission over energy barriers between layers describes the electron distribution, yielding the following expressions (Staudigel, J., et al., J. Appl. Phys. 1999, 86 (7), 3895-3910; Erickson, N. C. and Holmes, R. J., Adv. Funct. Mater. 2013, 23 (41), 5190-5198; Coburn, C., et al., Adv. Opt. Mater. 2016, 4 (6), 889-895):

$${j}_{n} ( x , t ) = q {μ}_{n} ( x , t ) n ( x , t ) E ( x , t ) - kT {μ}_{n} ( x , t ) \frac{\partial n ( x , t )}{\partial x} \qquad Equation 1$$

$$\frac{\partial E ( x , t )}{\partial x} = \frac{q}{ϵ} [ p ( x , t ) - n ( x , t ) ] \qquad Equation 2$$

$${μ}_{n} ( x , t ) = {μ}_{0} ( x ) {e}^{{( E ( x , t ) / {E}_{0} )}^{1 / 2}} \times \{ \begin{matrix}{e}^{\frac{∅ - Δ∅}{kT}} & ∅ > Δ∅ \\ 1 & ∅ < Δ∅\end{matrix} \qquad Equation 3$$

Here, jₙ is the electron current density, and E(x,t) is the electric field at position x and time t. Here, x=0 is at the EML/HTL interface. Also, q is the unit charge, n is the electron density, k is Boltzmann's constant, Tis the temperature, and μn is the local electron carrier mobility. The electron diffusion constant Dₙ is related to μn at equilibrium by the Einstein relation Dₙ=kTμn/q. Also, E is the dielectric constant of the material and p is the hole density. Charge transport across an interface between layers whose frontier orbital energies differ by c is based on the Miller-Abrahams model with Poole-Frenkel type field dependence in Equation 3 (Horowitz, G., Adv. Mater. 1998, 10, 365; Forrest, S. R., Organic Electronics: Foundations to Applications. Oxford University Press, Oxford, 2020). Finally, E₀ is the reference electric field for the reference mobility, μ₀, and ΔΦ=qEd is the energy difference induced by the potential drop across a layer of thickness d adjacent to the interface. The current density for holes, jₚ, is found by an analogous set of expressions.

By calculating the spatial distribution of electrons and holes, exciton generation in the EML is found assuming Langevin recombination at rate (Malliaras, G. G., J. Appl. Phys. 1999, 85 (10), 7426):

$${k}_{rec} = \frac{q}{ϵ} ( {μ}_{n} + {μ}_{p} ) np \qquad Equation 4$$

Here, it is assumed that all singlet excited states are transferred to triplets in phosphorescent emitters via intersystem crossing. They can either radiatively decay as governed by their lifetime τ or leave the generation site by diffusion. Neglecting second order processes such as exciton annihilation, the electron, hole, and exciton densities n(x,t), p(x,t), and N(x,t), respectively, are found using:

$$\frac{\partial n ( x , t )}{\partial t} = - \frac{q}{ϵ} ( {μ}_{n} + {μ}_{p} ) np - \frac{\partial {j}_{n} ( x , t )}{\partial x} \qquad Equation 5$$

$$\frac{\partial N ( x , t )}{\partial t} = \frac{q}{ϵ} ( {μ}_{n} + {μ}_{p} ) np - 1 / τ - {D}_{N} \frac{{\partial }^{2} N ( x , t )}{\partial {x}^{2}} \qquad Equation 6$$

The exciton diffusion constant, D_{N}, in the EML is calculated based on the average dopant molecular spacing (Forrest, S. R. Organic Electronics: Foundations to Applications. Oxford University Press, Oxford, 2020). A finite difference method is used to simulate the time-dependent solutions to Equations 5 and 6 until the steady state is reached (Coburn, C., et al., Adv. Opt. Mater. 2016, 4 (6), 889-895). The simulation is applied to the entire organic stack (>5 layers) within the OLED, including the role of the multiple energy barriers to both charge carriers. The boundary conditions are potential V=0 at the ETL/cathode interface, and V=Vₐ−V_{bi} at HTL/EML interface, where Vₐ denotes the applied voltage and V_{bi} is the built-in voltage. Charge neutrality is assumed across the transport layers and the EML. Ohmic contacts of the electrodes on the organic layers are assumed. The time-evolving iteration begins with the calculation of E(x,0) from the initial charge distribution, then sequentially calculates the local charge mobility and drift-diffusion currents and terminates by updating the charge density distribution. The exciton density at x is calculated after each iteration as the product of the electron and hole densities based on Equation 6.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL

A hole injecting/transporting material to be used in the present disclosure is not particularly limited, and any compound may be used as long as the compound is typically used as a hole injecting/transporting material.

### EBL

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host

The light emitting layer of the organic EL device of the present disclosure preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

As previously disclosed, OLEDs and other similar devices may be fabricated using a variety of techniques and devices. For example, in OVJP and similar techniques, one or more jets of material is directed at a substrate to form the various layers of the OLED.

### EXPERIMENTAL EXAMPLES

The invention is now described with reference to the following Examples. These Examples are provided for the purpose of illustration only and the invention should in no way be construed as being limited to these Examples, but rather should be construed to encompass any and all variations which become evident as a result of the teaching provided herein.

Without further description, it is believed that one of ordinary skill in the art can, using the preceding description and the following illustrative examples, make and utilize the present invention and practice the claimed methods. The following working examples therefore, specifically point out the preferred embodiments of the present invention, and are not to be construed as limiting in any way the remainder of the disclosure.

### Results

Compared herein are 4 WOLEDs (W1-W4) whose structures are shown schematically in FIG. 3A. The three phosphor-doped layers in the emission zone, and the total device thicknesses are identical for all devices. Compared to the control device (W1), a 5 nm-thick layer 311 of 4,40-bis(3-methylcarbazol-9-yl)-2,20-biphenyl (mCBP) or 4,4′-bis(N-carbazolyl)-1,1′-biphenyl (CBP) is inserted between EML and HTL in W2, or (301) in the middle of the HTL in W4. The neat CBP and mCBP layers serve as the BTL since their highest occupied molecular orbital (HOMO) energies of 6.0 eV is lower than the 5.6 eV HOMO energy of the surrounding HTL materials (namely, N,N′-Di(1-naphthyl)-N,N′-diphenyl-(1,1′-biphenyl)-4,4′-diamine (NPD) and 9-Phenyl-3,6-bis(9-phenyl-9Hcarbazol-3-yl)-9H-carbazole (Tris-PCz)), as shown in FIG. 3B. In both W3 and W4, 10 nm of the electron transporting layer (ETL) 305, 3,3′,5,5′-Tetra[(m-pyridyl)-phen-3-yl]biphenyl (BP4mPy) used in W1 and W2, is replaced by tris(8-hydroxyquinolinato)aluminum (Alq3) (see 306). Otherwise, W3 is identical to W1.

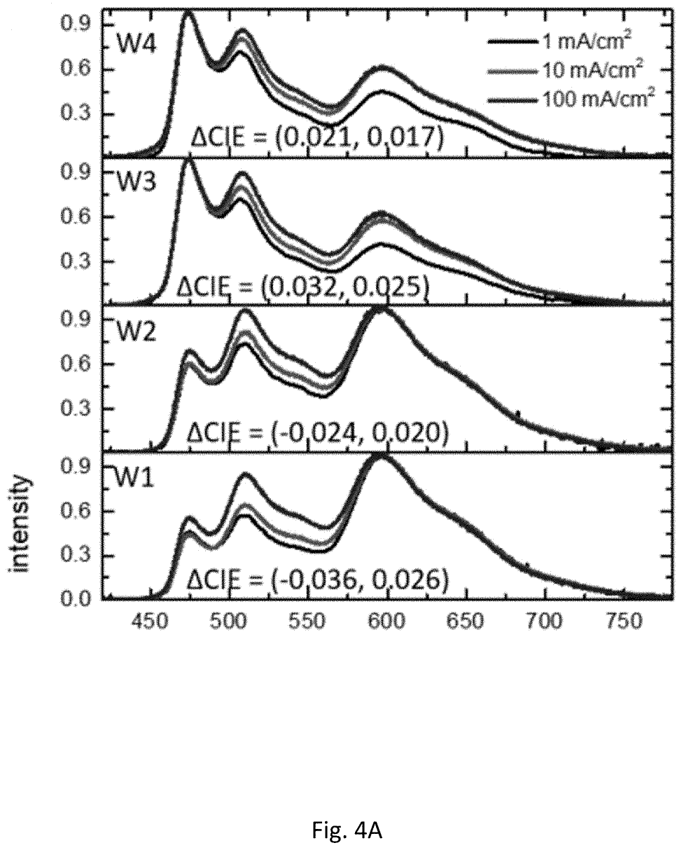

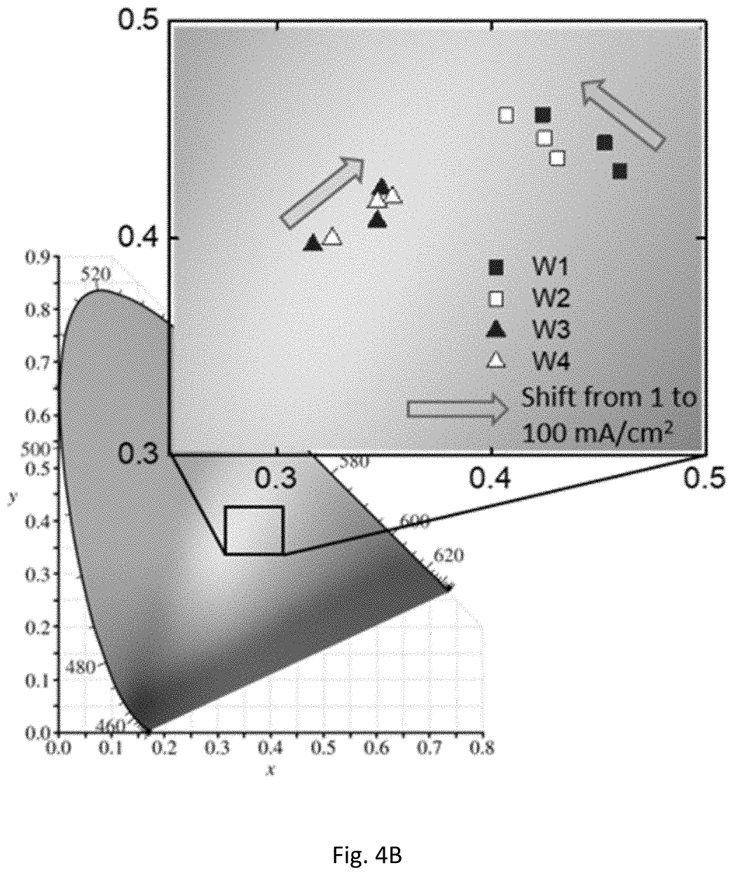

The normalized emission spectra of the four devices at current density (j)=1 to 100 mA/cm² are shown in FIG. 4A. The color coordinates of the corresponding spectra are compared in the CIE 1931 chromaticity diagram in FIG. 4B and summarized in Table 1.

TABLE 1
Emission colors and color shifts of WOLEDs W1-W4.

| | CRI | CCT | CIE | ΔCIE | ΔE_{ab}* | ΔCCT (K) | EQE (%) |
|---|---|---|---|---|---|---|---|
| | j = 10 mA/cm² | | | j = 1-100 mA/cm² | | | maximum |
| W1 | 80.0 | 3047 | (0.453, 0.444) | (−0.036, 0.026) | 18.0 ± 0.3 | 744 | 16 ± 1 |
| W2 | 78.7 | 3528 | (0.425, 0.446) | (−0.024, 0.020) | 13.1 ± 0.2 | 563 | 13 ± 1 |
| W3 | 71.8 | 5077 | (0.347, 0.408) | (0.032, 0.025) | 12.8 ± 0.2 | −942 | 15 ± 1 |
| W4 | 71.6 | 4899 | (0.354, 0.409) | (0.021, 0.017) | 8.6 ± 0.1 | −618 | 15 ± 1 |

White spectra present red, green and blue emission peaks originating from the phosphor dopants, iridium (III) bis(2-phenyl quinolyl-N,C20) acetylacetonate (PQIr), Tris(2-phenylpyridine)iridium(III) (Ir(ppy)3), and fac-tris[(2,6-diisopropylphenyl)-2-phenyl-1H-imidazol[e]iridium(III) (Ir(iprpmi)3), respectively. As j increases, the WOLED spectra blue-shift in W1 and W2, and red-shift in W3 and W4, which corresponds to a positive and negative change in correlated color temperature, ACCT, respectively. The change of CCT is smaller in devices with the BTLs. The color-shift, ΔCIE, in devices with the BTLs is reduced from (−0.036, 0.026) and (0.032, 0.025), to (−0.024, 0.020) and (0.021, 0.017) in devices W1 and W2, and W3 and W4, respectively, due to BTLs inserted in W2 and W4. The measure of change in visual perception of two colors, ΔEab*, defined as Euclidian distance between two points in CIELab 1976 color space, is also reduced from 18.0±0.3 to 13.1±0.2 (W1 to W2), and 12.8±0.2 to 8.6±0.1 (W3 to W4) by the BTLs.

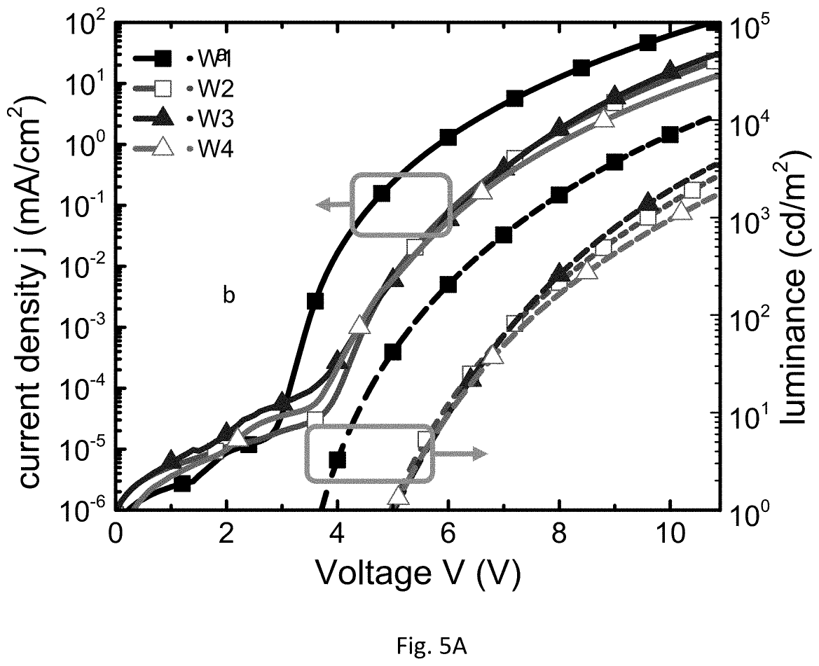

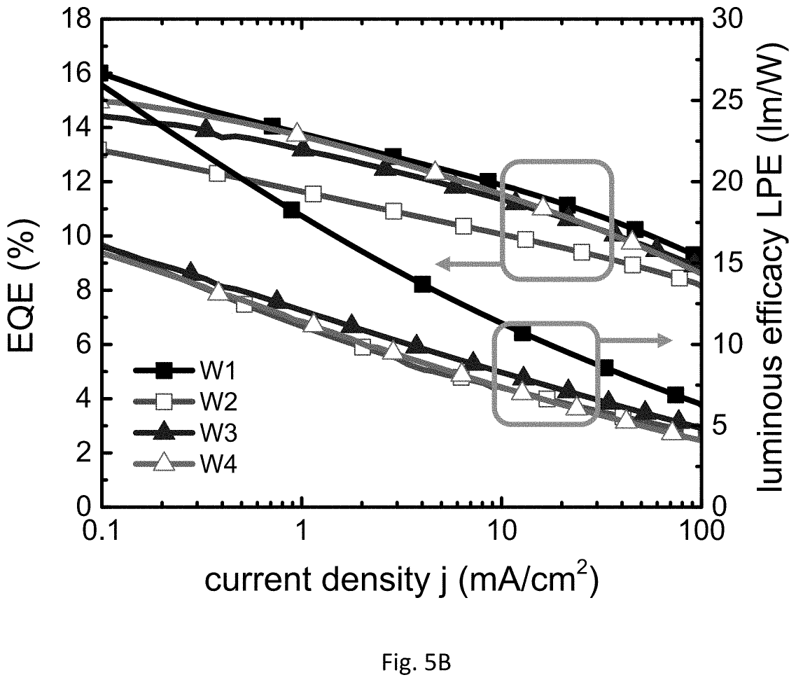

The current density-Voltage-luminance (j-V-L) and efficiency characteristics of the devices are shown in FIG. 5A and FIG. 5B. Inserting an mCBP BTL in W2 or an Alq₃ ETL in W3 and W4 results in an increase of the turn-on voltage (corresponding to the forward bias required to conduct j=0.1 μA/cm²) due to the added energy barrier. Consequently, the luminance and luminous power efficacy (LPE) of devices W2-W4 are comparable, but lower than W1 at all voltages. The employment of a CBP BTL in W4 causes a negligible change in j-V characteristics compared with W3. The quantum efficiencies of W3 and W4 are comparable to the control device, W1, with EQE=15±1% at 0.1 mA/cm². The quantum efficiency of W2 is lower due to electron leakage through the neat mCBP BTL, and non-radiative recombination at the HTL/BTL interface.

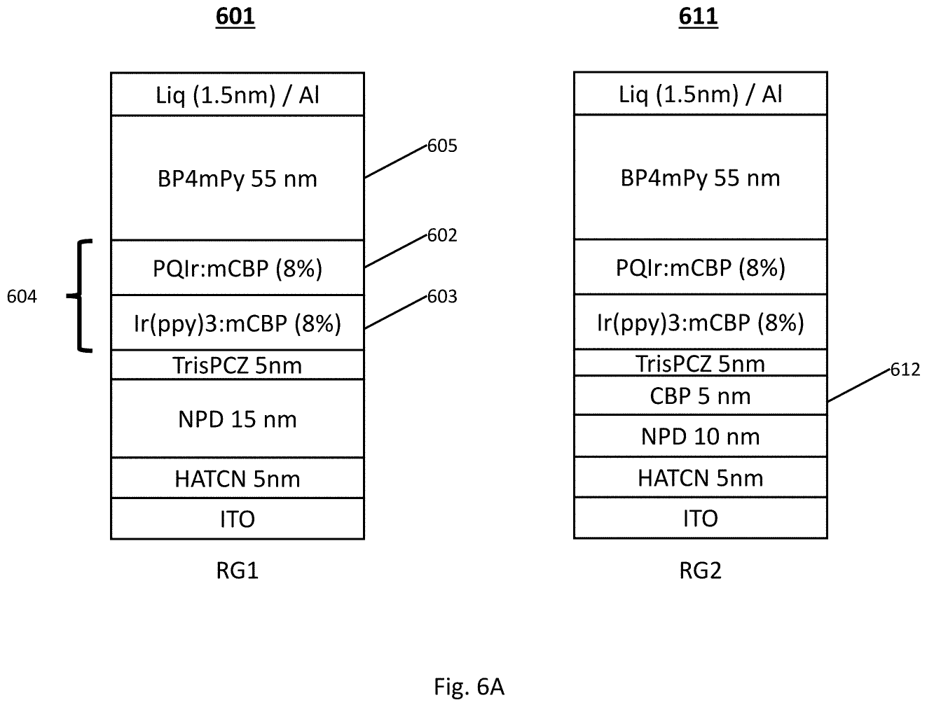

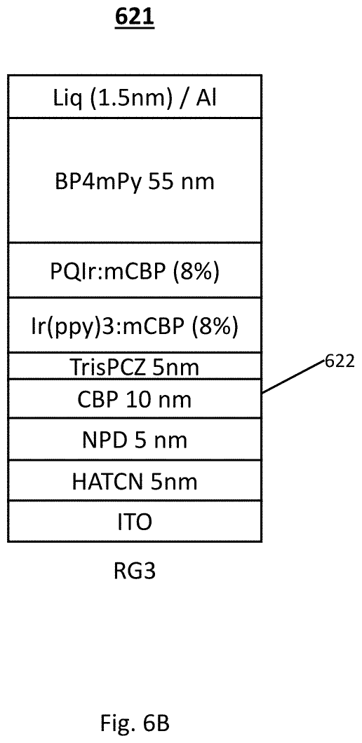

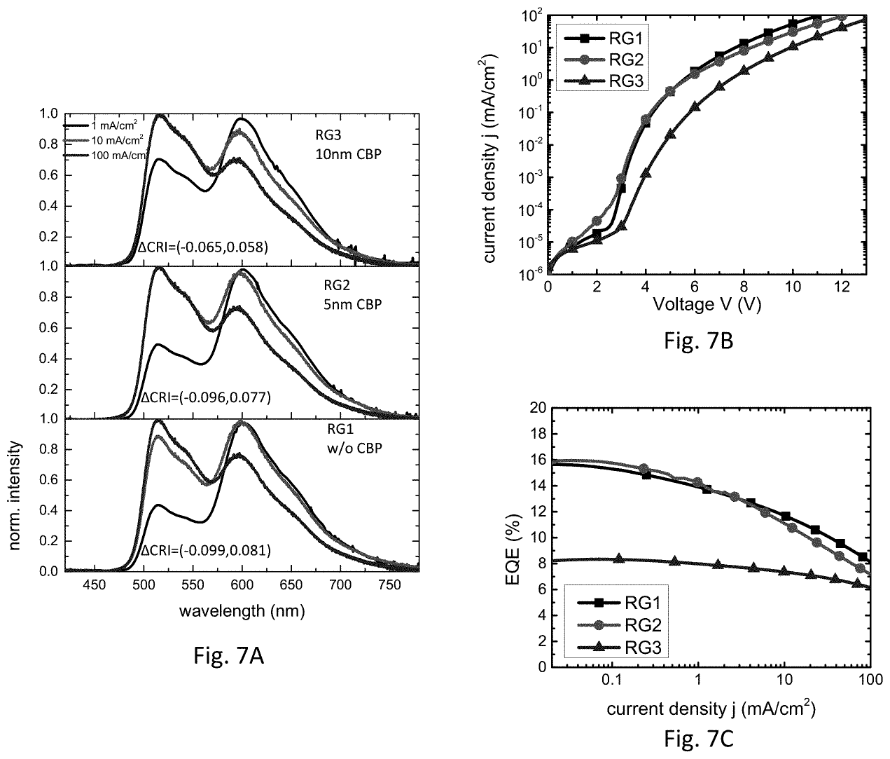

With reference to FIG. 6A and FIG. 6B, to investigate the function of the BTLs, two-color red-green OLEDs (RG1, RG2, RG3) were fabricated with emission zones 604 comprising a 15 nm-thick red-emitting PQIr doped mCBP (vol. 8%) layer 602 on a 15 nm-thick green-emitting Ir(ppy)₃ doped mCBP (vol. 8%) layer 603. Device RG1 601 replaces the EML and ETLs in W3 with a two-color EML 604 and a 55 nm thick BP4mPy ETL 605, respectively. Device RG2 (611) employs the same material change to W4, as RG1 employs to W3. Device RG3 (621) is the same as RG2 except the CBP BTL 622 thickness is increased to 10 nm. The j-V-EQE and spectral characteristics of the three devices are shown in FIG. 7A, FIG. 7B, and FIG. 7C. As j increases from 1 to 100 mA/cm², the intensity of the green emission relative to the red increases for all three OLEDs, suggesting that the exciton formation zones shift from regions near the ETL, towards the HTL. The color-shift of RG2 (ΔCIE=(−0.096, 0.077)) is smaller than RG1 ((ΔCIE=(−0.099, 0.081)) since the BTL mitigates the exciton formation zone shift. The 5 nm thick BTL 612 in RG2 induces negligible change in turn-on voltage and EQE relative to RG1. The thicker BTL 622 in RG3 results in the smallest ΔCIE=(−0.065, 0.058) among the three, but also causes an increase in turn-on voltage and a reduction in EQE.

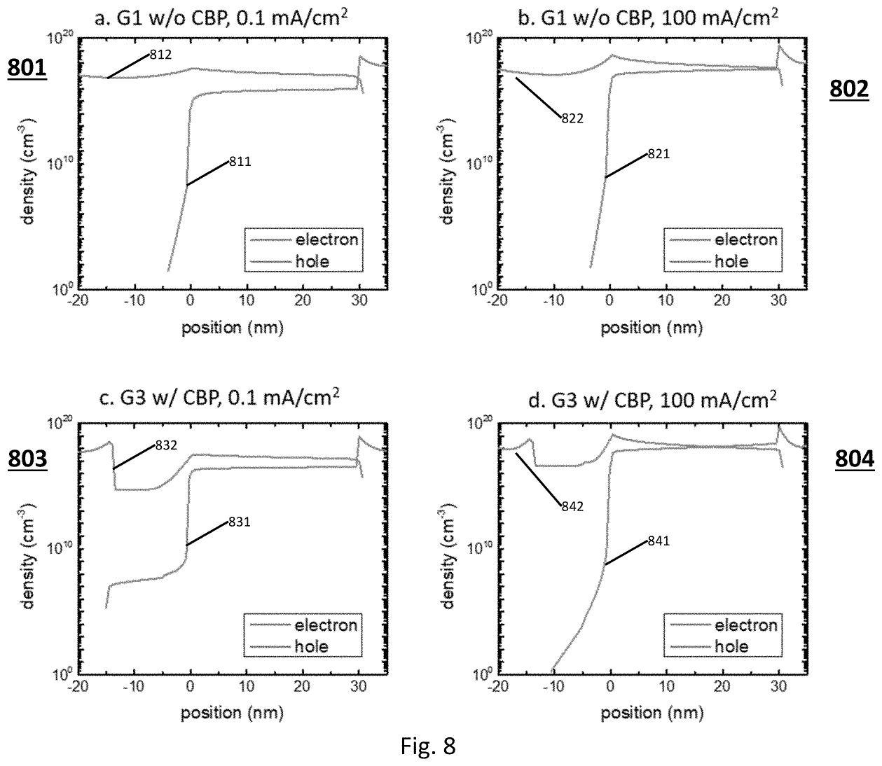

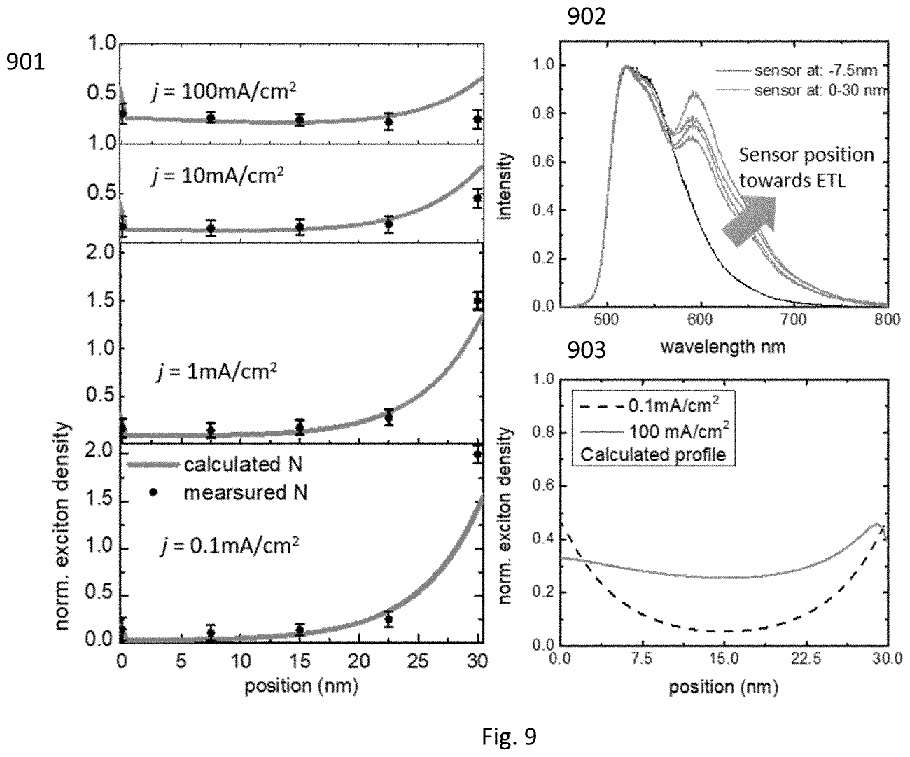

To understand the dependence of the exciton density, N, on the BTL, the charge and exciton dynamics using Equations. 1-6 were simulated. The numerical model was applied to 2 multilayer systems (G1 and G3) that are similar to RG1 and RG3, where all transport and blocking layers in RG1 and RG3 are included, yet the emission zones were replaced by only a single, 30 nm-thick green-emitting Ir(ppy)₃ doped mCBP (vol. 8%) EML. The calculations employ one-dimensional 0.5 nm mesh grids, with the origin at the EML/HTL interface. The calculated n and p distribution within G1 and G3 at j=0.1 and 100 mA/cm² are shown in FIG. 8. In G1, n is significantly lower than p in the EML at 0.1 mA/cm² because the lowest unoccupied molecular orbital (LUMO) energy barrier at the mCBP/BP4mPy interface (at x=30 nm) limits electron injection (graph 801). At high currents, more electrons overcome the mCBP/BP4mPy barrier with the help of the increased field (graph 802). The electron density in HTLs is nearly zero in G1, suggesting complete electron blocking at the Tris-PCz/EML interface. In G3, p decreases at the NPD/BTL interface (x=−15 nm) because the NPD/CBP HOMO barrier impedes hole injection. The relative difference between n and p in the EML in G3 is smaller than in G1 at both current densities, indicating the BTL improves the charge balance (graphs 8C and 8D). The larger n in the HTL (at −5≤x≤0 nm) of G3 compared to G1 suggests electron leakage through Tris-PCz/EML interface when a thick BTL is employed. In FIGS. 8, 811, 821, 831, and 841 are the electron density, and 821, 822, 832, and 842 are the hole density.

The calculated exciton profile in the EML of G1 is shown in graph 901 in FIG. 9 (solid lines). At j=0.1 mA/cm², most excitons form near the EML/ETL interface. As j increases, N near the HTL/EML interface monotonically increases, which matches the increase in green emission in device RG1. To verify the model, N(x) was measured in device G1 by inserting ultrathin (0.1 nm) PQIr phosphor sensing layers at 7.5 nm intervals in the EMLs in five separate, but otherwise identical OLEDs. An additional sensor was placed in the HTL at x=−7.5 nm to measure exciton leakage. These sensors trapped the high energy triplets with negligible influence on the charge transport, leading to red emission whose intensity is proportional to N at that location. The measured sensor emission intensities are shown in graph 901 of FIG. 9 at j=0.1, 1, and 10, and 100 mA/cm² (data points, bottom to top). As an example, the sensor emission spectra at 10 mA/cm² are compared with the bulk green emission in graph 902 of FIG. 9. There is no red emission from the sensor in the HTL, indicating effective exciton confinement within the EML in G1. The measured local exciton density was obtained by deconvoluting the red emission from the overall spectrum, and normalizing the red relative to green emission peak intensity. The calculated N(x) profile was normalized to its integral of over 0≤x≤30 nm in the EML. This integral is proportional to the bulk EML green emission intensity. At j<1 mA/cm², N at the EML/ETL interface is much larger than that at EML/HTL interface, whereas at j=100 mA/cm², N is nearly uniform across the EML with its peak at the EML/HTL interface. The calculated N profile reasonably matches the measured data at all current densities studied for device G1. The calculated N(x) for device G3 at two different current densities are shown in graph 903 of FIG. 9. The BTL significantly reduces the change in N(x) with j. For example, at j=0.1 mA/cm², N(x) peaks at both ends of the EML, creating a more balanced profile compared to G1 in graph 901 of FIG. 9. The exciton profile becomes more uniformly spread across the EML as j increases to 100 mA/cm².

### DISCUSSION

The spectral shift is primarily controlled by charge injection barriers at the periphery of the EML. In devices W1-W4, the phosphor-doped layers were arranged such that charge transport barriers were absent within the EMLs themselves (see FIG. 3B). In devices W1 and W3, holes are injected from the HTLs directly into the Ir(ppy)₃ HOMO across a negligible energy barrier (Reineke, S., et al., Phys. Rev. B. 2007, 75, 125328). Hole currents can be approximated by space charge limited conduction (SCLC) due to the significantly lower mobility in EMLs compared to the transport layers (Nguyen, N. D., et al., Phys. Rev. B. 2007, 75 (7), 075307). However, electron transport from the ETL to the hosts in devices W1-W4 is limited by the 0.2 eV barrier at the LUMOs between BP4mPy and mCBP, shown in FIG. 3B. Such barriers are common in white and blue OLEDs since the use of high energy gap host materials often results in LUMOs of energy higher than that of the ETL (Lee, J., et al., Nat. Mater. 2016, 15 (1), 92-98). The injection-limited electron conduction regime is different from the SCL hole conduction, which leads to an unbalanced charge population in the EMLs. At low voltages, holes accumulate at the EML/ETL interface and form a large local exciton density. As the applied voltage Vₐ increases, the electric field E at the ETL/EML interface increases proportionately, causing jₙ to increase with voltage at a power law of larger than 2 (Baldo, M. A. and Forrest, S. R. Phys. Rev. B. 2001, 64, 085201). The large increasing rate of jₙ with Vₐ exceeds that of jₚ (quadratic with Vₐ), resulting in a deeper penetration of electrons into the EML. This leads to the shift in the exciton formation zone from the ETL to the HTL side of the EML, which agrees with the green emission enhancement observed in devices W1, W3, and RG1 with increasing j.

An BTL with a low HOMO energy creates an injection barrier to holes, analogous to that for electrons at the EML/ETL interface. The similar conduction regimes for holes and electrons provide improved charge balance, leading to broader exciton formation zones, and hence spectra that are largely independent of current. Thus, the CBP BTL in device W4 yields the smallest color shift with ΔEab*=8.6±0.1 as j is varied from 1 to 100 mA/cm², which is more than a 50% improvement over device W1. For reference, in the CIELab 1976 color space, ΔEab*=1 is considered as one unit of “just noticeable difference” (JND), which is equivalent to the color range within a 1-step MacAdam ellipse (Abeyta, R. N., Embry-Riddle Aeronautical University 2001).

Careful control of the position and thickness of the BTL in an OLED is essential to avoid improving spectral stability at the expense of the quantum efficiency, as in device W2. In device W4, the CBP BTL is placed between NPD and Tris-PCz so that Tris-PCz (triplet energy=2.8 eV) layer blocks triplet diffusion while preventing electron leakage from the EML to the CBP BTL. The EQE of device W4 is hence similar to W3, as shown in FIG. 5B. The addition of a single charge blocking layer embedded in the transport layers provides a simple means to stabilize the emission spectra without modifying or impacting the integrity of the EML. The bulk charge trap and surface defect states that may be induced by the contact of EML with the blocking layer are avoided. While the LPE of device W4 is comparable to W3, they are both lower than that of W1, where only one smaller energy barrier is present. When the Alq₃ layer introduces an additional LUMO barrier to device W3, the turn-on voltage of W3 is higher than W1 because a larger electric field is required to inject the charge. The LPE of device W3 is therefore reduced even though the EQE is nearly unchanged compared to W1. Insertion of the 5 nm thick BTL in W4 creates a smaller or nearly symmetrical HOMO energy barrier compared to the existing LUMO barrier, but only induces a negligible change in the turn-on voltage. This may stem from a conduction path that forms when the density of states in the CBP and NPD HOMOs broadens and overlaps at their interface (Baldo, M. A. and Forrest, S. R., Phys. Rev. B. 2001, 64, 085201; Li, P., et al., Commun. Phys. 2019, 2 (1), 1-7). In devices RG2 and RG3, the color shift and efficiency are both reduced as the BTL thickness increases. Excessively thick BTLs may create a large internal resistance that increases the OLED turn-on voltage, and a concomitant loss in power efficiency (see FIG. 7B and FIG. 7C). The accumulation of holes at the thick BTL can increase the local electric field, which drives electrons from the EML to the BTL where they non-radiatively recombine.

The parameters used in the simulations to calculate n, p, and Nin FIG. 8 and FIG. 9 are summarized in Table 2:

TABLE 2
Parameters used in simulations

| | Parameter | | Value |
|---|---|---|---|
| Fixed | μₙ (cm²/Vs) | EML | 5.8 ± 0.2 × 10⁻⁷ |
| | | ETL | 6.5 ± 0.2 × 10⁻⁵ |
| | μₚ (cm²/Vs) | HTL | 2.5 ± 0.5 × 10⁻⁴ |
| | | CBP | 4.6 ± 0.2 × 10⁻⁴ |
| | E₀ (V/cm) | | 1.7 ± 0.1 × 10⁶ |
| | D_{N} (cm²/s) | | 4.1 ± 0.1 × 10⁻⁷ |
| | τ (ns) | | 615 ± 7 |
| | d (nm) | | 1 |
| | V_{bi} (V) | | 3.0 ± 0.2 |
| | T (K) | | 297 |
| | ε/ε₀ | | 3.1 |
| Fitted | μₚ (cm²/Vs) | EML | 5.0 ± 0.1 × 10⁻⁷ |

The hole mobility in the EMLs of G1 and G3 is 5.0±0.1×10−7 cm²/Vₛ, obtained by fitting the measured N profile of device G1 to the calculated results in graph 901 in FIG. 9. In graphs 801 and 802 of FIG. 8, the simulated charge density profile for G1 indicates N(x) is controlled by n, since p is in excess of the electron density across the entire EML. Employing a 10 nm thick CBP BTL in G3 creates nearly symmetrical n and p distribution profiles at both studied voltages in graphs 803 and 804, indicating jₙ and jₚ increase with Vat comparable rates. The notable increase of n in the HTL of G3 compared to G1 leads to increased nonradiative charge recombination, providing an efficiency loss channel. This is supported by the observation of red emission from the sensor layer embedded in the CBP BTL in device G3. In graph 901 of FIG. 9, N(x) is calculated based on the product of n(x) and p(x), which is consistent with measurement. This suggests that triplet formation in phosphorescent OLEDs is mostly via direct charge trapping on dopant molecules, instead of via the energy transfer from the hosts to the dopants. In graph 903 of FIG. 9, the BTL not only preserves the symmetrical shape of N(x) across the EML at all currents, but also eliminates regions with large N. This implies BTLs may reduce triplet-triplet annihilation by avoiding regions with a high density of excitons (Giebink, N. C., et al., J. Appl. Phys. 2008, 103 (4)).

### CONCLUSION

The spectral shift of a WOLED is reduced in terms of ΔCIE and ΔE_{ab}* from (0.032, 0.025) to (0.021, 0.017), and from 12.8±0.2 to 8.6±0.1, respectively by inserting a CBP BTL. This design concept reduces the original color shift to a “9-step MacAdam ellipse”, which is closer to the recommended chromaticity range for general solid state lighting products, whose color space should lie within a “7-step MacAdam ellipse” (American National Standard for Electric Lamps—Specifications for the Chromaticity of Solid State Lighting (SSL) Products. ANSI 2017). The resulting device shows EQE=15±1% at 0.1 mA/cm² and comparable j-V characteristics to the device without a BTL. However, the introduction of the HOMO barrier associated with the BTL can induce a luminous efficacy drop, unless a larger LUMO barrier (Alq₃/BP4mPy barrier in W3) exists previously in the device. A numerical model is introduced to describe the charge transport and exciton distribution in OLEDs with or without BTLs, which is validated by measuring emission of phosphor sensors embedded across the device. Unbalanced charge injection from asymmetrical energy barriers for electrons and holes is found to be the origin of intensity-dependent color shift. The disclosed study suggests that the introduction of BTLs leads to a uniform exciton distribution profile in EML that stabilizes WOLED spectra as current is varied over two orders of magnitude. The BTL design and detailed knowledge of the current-dependent exciton profile from our numerical model provide an opportunity to engineer high quality WOLED lighting sources.

All layers were grown by vacuum thermal evaporation at a base pressure of 10⁻⁷ Torr on glass substrates with pre-patterned, 1 mm wide indium tin oxide (ITO) anode strips giving device areas of 1 mm². The device structures are 70 nm ITO anode/5 nm hexaazatriphe-nylene hexacarbonitrile (HATCN) hole injection layer/20 nm HTL/ETL/55 nm ETL/1.5 nm thick 8-hydroxyquinolinato lithium (Liq) electron injection layer/100 nm thick Al cathode. The emission zone for WOLEDs are 5 nm Ir(ppy)3:mCBP (8% vol.)/10 nm PQIr:mCBP (4% vol.)/10 nm Ir(iprpmi)3:mCBP (13% vol.). The emission zones for two-color OLEDs are 15 nm Ir(ppy)3:mCBP (8% vol.)/15 nm PQIr:mCBP (8% vol.). The EML for devices G1 and G3 is 30 nm Ir(ppy)3:mCBP (8% vol.). The detailed structures for the HTLs and ETLs are summarized in Table 3:

TABLE 3
Detailed structures of HTLs and ETLs.

| Device | HTL | ETL |
|---|---|---|
| W1, RG1, and G1 | 15 nm NPD/5 nm Tris-PCz | 55 nm BP4mPy |
| W2 | 10 nm NPD/5 nm Tris-PCz/5 nm mCBP | 55 nm BP4mPy |
| W3 | 15 nm NPD/5 nm Tris-PCz | 45 nm BP4mPy/10 nm Alq₃ |
| W4 | 10 nm NPD/5 nm CBP/5 nm Tris-PCz | 45 nm BP4mPy/10 nm Alq₃ |
| RG2 | 10 nm NPD/5 nm CBP/5 nm Tris-PCz | 55 nm BP4mPy |
| RG3 and G3 | 5 nm NPD/10 nm CBP/5 nm Tris-PCz | 55 nm BP4mPy |

The 0.1 nm thick neat PQIr sensing layers were located at x=—7.5, 0.0, 7.5, 15.0, 22.5, and 30.0±0.1 nm in device G1, and x=—7.5±0.1 nm in device G3. The electroluminescent spectra of all devices were collected via a spectrometer using a lens-coupled fiber. The j-V-EQE characteristics of the PHOLEDs were measured using a parameter analyzer and a calibrated photodiode that collected all light exiting the substrates in the viewing direction.

The parameters used in the simulations were determined as follows: DN was calculated to be 4.1±0.1×10⁻⁷ cm²/s based on the average dopant molecular spacing of 2.3 nm (8% doping vol.) and the exciton Bohr radius of 1.6 nm.38 The Ir(ppy)₃ triplet lifetime is τ=615±7 ns measured from its time-resolved photoluminescence (Zhang, Y., et al., Chem. Phys. Lett. 2013, 590, 106-110). The electron mobility of the ETLs and mCBP, and the hole mobility of the HTLs and CBP at E₀=1.7×10⁶ V/cm were obtained from the literature (Nguyen, N. D., et al., Phys. Rev. B. 2007, 75 (7), 075307; Liu, N., et al., Micromachines 2019, 10 (5); Parshin, M. A., et al., SPIE Photonics Europe. 2006, 6192, 419). The hole mobility in the ETLs was assumed to be significantly lower (by a factor of 10⁻³) than the electron mobility for simplicity. The electron mobility in the HTLs was assumed to be less than that of holes by the same factor. Also, c was based on the energy diagram from FIG. 3B with an error of ±0.1 eV. The barrier width, d, was set to 1 nm, which covers two unit-grids. Finally, Ohmic contacts to the transport layers were assumed, (Lin, H. W., et al., Org. Electron. 2013, 14 (4), 1204-1210) in which case V_{bi}=3.0±0.2 V is the potential difference between the HOMO of NPD and the LUMO of BP4mPy. The Vₐ for each j was extracted from the j-V characteristics in FIG. 7B.

### REFERENCES

The following publications are incorporated herein by reference in their entireties:
Coburn, C.; Jeong, C.; Forrest, S. R. Reliable, All-Phosphorescent Stacked White Organic Light Emitting Devices with a High Color Rendering Index. ACS Photonics 2018, 5, 630-635
Kato, K.; Iwasaki, T.; Tsujimura, T. Over 130 Lm/W All-Phosphorescent White OLEDs for next-Generation Lighting. J. Photopolym. Sci. Technol. 2015, 28 (3), 335-340.
Qu, B.; Ding, K.; Sun, K.; Hou, S.; Morris, S.; Shtein, M.; Forrest, S. R. Fast Organic Vapor Phase Deposition of Thin Films in Light-Emitting Diodes. ACS Nano 2020, 14
Sasabe, H.; Kido, J. Development of High Performance OLEDs for General Lighting. J. Mater. Chem. C 2013, 1 (9), 1699-1707.
Andrade, B. B. W. D.; Thompson, M. E. Controlling Exciton Diffusion in Multilayer White Phosphorescent Organic Light Emitting Devices. Adv. Mater. 2002, 2, 147.
Sun, Y.; Giebink, N. C.; Kanno, H.; Ma, B.; Thompson, M. E.; Forrest, S. R. Management of Singlet and Triplet Excitons for Efficient White Organic Light-Emitting Devices. Nature 2006, 440, 908
Zhao, C.; Zhang, T.; Chen, J.; Yan, D.; Ma, D. High-Performance Hybrid White Organic Light-Emitting Diodes with Simple Emitting Structures and Low Efficiency Roll-off Based on Blue Thermally Activated Delayed Fluorescence Emitters with Bipolar Transport Characteristics. J. Mater. Chem. C 2018, 6 (35), 9510-9516.
Sun, Q.; Chang, D. W.; Dai, L.; Grote, J.; Naik, R. Multilayer White Polymer Light-Emitting Diodes with Deoxyribonucleic Acid-Cetyltrimetylammonium Complex as a Hole-Transporting/Electron-Blocking Layer. Appl. Phys. Lett. 2008, 92 (25), 251108.
Li, J.; Chen, T.; Yang, J.; Cao, J. Realizing the Stable Spectrum in Four-Chromatic White Organic Light-Emitting Diodes by Controlling the Positions of Various Emitters in the Bipolar Interlayer. J. Phys. D. Appl. Phys. 2021, 54 (16), 165105.
Gather, M. C.; Alle, R.; Becker, H.; Meerholz, K. On the Origin of the Color Shift in White-Emitting OLEDs. Adv. Mater. 2007, 19 (24), 4460-4465.
Wang, Q.; Yu, J.; Zhao, J.; Li, M.; Lu, Z. Enhancement of Charge Carrier Recombination Efficiency by Utilizing a Hole-Blocking Interlayer in White OLEDs. J. Phys. D. Appl. Phys. 2013, 46 (15), 155102.
Yang, F.; Kou, Z.; Yang, L.; Tang, Y. Influence of the Hole Transport Layer on Spectral Stability in the White Phosphorescent Organic Light Emitting Diode with Non-Doped Structure. Opt. Mater. (Amst). 2018, 82, 130-134.
Loeser, F.; Romainczyk, T.; Rothe, C.; Pavicic, D.; Haldi, A.; Hofmann, M.; Murano, S.; Canzler, T. W.; Birnstock, J. Improvement of Device Efficiency in PIN-OLEDs by Controlling the Charge Carrier Balance and Intrinsic Outcoupling Methods. J. Photonics Energy. 2012, 2, 021207.
Altazin, S.; Kirsch, C.; Knapp, E.; Stous, A.; Ruhstaller, B. Refined Drift-Diffusion Model for the Simulation of Charge Transport across Layer Interfaces in Organic Semiconductor Devices. J. Appl. Phys. 2018, 124 (13), 135501.
Ruhstaller, B.; Carter, S. A.; Barth, S. Transient and Steady-State Behavior of Space Charges in Multilayer Organic Light-Emitting Diodes. J. Appl. Phys. 2001, 89, 4575.
Arkhipov, V. I.; Emelianova, E. V; Bassler, H. Charge Carrier Transport and Recombination at the Interface between Disordered Organic Dielectrics. J. Appl. Phys. 2001, 90, 2352.
Lu, F.; Peng, Y.; Xing, Y. Numerical Model of Tandem Organic Light-Emitting Diodes Based on a Transition Metal Oxide Interconnector Layer. J. Semicond. 2014, 35, 044005.
Staudigel, J.; StöBel, M.; Steuber, F.; Simmerer, J. A Quantitative Numerical Model of Multilayer Vapor-Deposited Organic Light Emitting Diodes. JAP 1999, 86 (7), 3895-3910.
Erickson, N. C.; Holmes, R. J. Investigating the Role of Emissive Layer Architecture on the Exciton Recombination Zone in Organic Light-Emitting Devices. Adv. Funct. Mater. 2013, 23 (41), 5190-5198.
Coburn, C.; Lee, J.; Forrest, S. R. Charge Balance and Exciton Confinement in Phosphorescent Organic Light Emitting Diodes. Adv. Opt. Mater. 2016, 4 (6), 889-895.
Horowitz, G. Organic Field-Effect Transistors. Adv. Mater. 1998, 10, 365.
Forrest, S. R. Organic Electronics: Foundations to Applications. Oxford University Press, Oxford, 2020.
Malliaras, G. G.; Scott, J. C. Numerical Simulations of the Electrical Characteristics and the Efficiencies of Single-Layer Organic Light Emitting Diodes. J. Appl. Phys. 1999, 85
Li, T. Y.; Wu, J.; Wu, Z. G.; Zheng, Y. X.; Zuo, J. L.; Pan, Y. Rational Design of Phosphorescent Iridium(III) Complexes for Emission Color Tunability and Their Applications in OLEDs. Coord. Chem. Rev. 2018, 374, 55-92.
Nakanotani, H.; Masui, K.; Nishide, J.; Shibata, T.; Adachi, C. Promising Operational Stability of High-Efficiency Organic Light-Emitting Diodes Based on Thermally Activated Delayed Fluorescence. Sci Rep. 2013. 3, 2127.
Lee, J.; Jeong, C.; Batagoda, T.; Coburn, C.; Thompson, M. E.; Forrest, S. R. Hot Excited State Management for Long-Lived Blue Phosphorescent Organic Light-Emitting Diodes. Nat. Commun. 2017, 8 (1), 1-9.
Klubek, K. P.; Tang, C. W.; Rothberg, L. J. Investigation of Blue Phosphorescent Organic Light-Emitting Diode Host and Dopant Stability. Org. Electron. 2014, 15 (7), 1312-1316.
Himmetoglu, B.; Marchenko, A.; Dabo, I.; Cococcioni, M. Role of Electronic Localization in the Phosphorescence of Iridium Sensitizing Dyes. J. Chem. Phys. 2012, 137 (15), 154309.
Zhang, Y.; Lee, J.; Forrest, S. R. Tenfold Increase in the Lifetime of Blue Phosphorescent Organic Light-Emitting Diodes. Nat. Commun. 2014, 5 (1), 1-7.
Reineke, S.; Walzer, K.; Leo, K. Triplet-Exciton Quenching in Organic Phosphorescent Light-Emitting Diodes with Ir-Based Emitters. Phys. Rev. B. 2007, 75, 125328.
Nguyen, N. D.; Schmeits, M.; Loebl, H. P. Determination of Charge-Carrier Transport in Organic Devices by Admittance Spectroscopy: Application to Hole Mobility in α-NPD. Phys. Rev. B. 2007, 75 (7), 075307.
Lee, J.; Chen, H. F.; Batagoda, T.; Coburn, C.; Djurovich, P. I.; Thompson, M. E.; Forrest, S. R. Deep Blue Phosphorescent Organic Light-Emitting Diodes with Very High Brightness and Efficiency. Nat. Mater. 2016, 15 (1), 92-98.
Baldo, M. A.; Forrest, S. R. Interface-Limited Injection in Amorphous Organic Semiconductors. Phys. Rev. B. 2001, 64, 085201.
Abeyta, R. N. The Distance between Colors: Using DeltaE* to Determine Which Colors Are Compatible. PhD Dissertations and Master's Thesis. Embry-Riddle Aeronautical University 2001.
Li, P.; Ingram, G.; Lee, J. J.; Zhao, Y.; Lu, Z. H. Energy Disorder and Energy Level Alignment between Host and Dopant in Organic Semiconductors. Commun. Phys. 2019, 2 (1), 1-7.
Giebink, N. C.; D'Andrade, B. W.; Weaver, M. S.; MacKenzie, P. B.; Brown, J. J.; Thompson, M. E.; Forrest, S. R. Intrinsic Luminance Loss in Phosphorescent Small-Molecule Organic Light Emitting Devices Due to Bimolecular Annihilation Reactions. J. Appl. Phys. 2008, 103 (4).
American National Standard for Electric Lamps—Specifications for the Chromaticity of Solid State Lighting (SSL) Products. ANSI 2017.
Zhang, Y.; Forrest, S. R. Triplet Diffusion Leads to Triplet-Triplet Annihilation in Organic Phosphorescent Emitters. Chem. Phys. Lett. 2013, 590, 106-110.
Liu, N.; Mei, S.; Sun, D.; Shi, W.; Feng, J.; Zhou, Y.; Mei, F.; Xu, J.; Jiang, Y.; Cao, X. Effects of Charge Transport Materials on Blue Fluorescent Organic Light-Emitting Diodes with a Host-Dopant System. Micromachines 2019, 10 (5).
Parshin, M. A.; Ollevier, J.; Van der Auweraer, M. Charge Carrier Mobility in CBP Films Doped with Ir(ppy)3. SPIE Photonics Europe. 2006, 6192, 419.
Lin, H. W.; Lin, W. C.; Chang, J. H.; Wu, C. I. Solution-Processed Hexaazatriphenylene Hexacarbonitrile as a Universal Hole-Injection Layer for Organic Light-Emitting Diodes. Org. Electron. 2013, 14 (4), 1204-1210.

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention.

What is claimed is:

1. An organic light emitting device, comprising:
an anode;
a first hole transport layer positioned over the anode;
a barrier transport layer positioned over the first hole transport layer;
a second hole transport layer positioned over the barrier transport layer;
at least one emissive layer positioned over the second hole transport layer; and
a cathode positioned over the at least one emissive layer.

2. The organic light emitting device of claim 1, wherein the barrier transport layer is positioned in direct contact with the first and second hole transport layers.

3. The organic light emitting device of claim 1, wherein the first and second hole transport layers have the same composition.

4. The organic light emitting device of claim 1, wherein the first hole transport layer comprises a material not present in the second hole transport layer.

5. The organic light emitting device of claim 1, wherein the barrier transport layer comprises a hole blocking material with a highest occupied molecular orbital energy that is lower than the that of a material included in the first and second hole transport layers.

6. The organic light emitting device of claim 5, wherein the hole blocking material possesses high carrier mobilities.

7. The organic light emitting device of claim 6, wherein the barrier transport layer is configured to reduce a shift of a location of exciton formation with changes in current.

8. The organic light emitting device of claim 1, the at least one emissive layer comprising a plurality of emissive layers.

9. The organic light emitting device of claim 1, the device configured to emit white light.

10. The organic light emitting device of claim 1, wherein the emissive layer has a thickness between 5 nm and 100 nm.

11. The organic light emitting device of claim 1, further comprising an electron transport layer positioned between the cathode and the emissive layer.

12. The organic light emitting device of claim 11, wherein the electron transport layer comprises at least first and second electron transport sublayers, wherein the first electron transport sublayer comprises a material different from the second electron transport sublayer.

13. An organic light emitting device, comprising:
an anode and a cathode;
an emissive layer having an anode-facing surface and a cathode-facing surface, positioned between the anode and the cathode;
a first hole transport layer positioned between the anode and the emissive layer; and
a barrier transport layer positioned between the anode and the emissive layer, at a distance from the anode-facing surface of the emissive layer of between 1 nm and 50 nm.

14. The organic light emitting device of claim 13, further comprising a second hole transport layer positioned between the anode and the emissive layer.

15. The organic light emitting device of claim 14, wherein the barrier transport layer is positioned between the first and second hole transport layers.

16. The organic light emitting device of claim 13, wherein the barrier transport layer is positioned between the anode and the emissive layer at a distance from the anode-facing surface of the emissive layer of between 1 nm and 10 nm.

17. The organic light emitting device of claim 13, further comprising an electron transport layer positioned between the emissive layer and the cathode.

18. The organic light emitting device of claim 17, wherein the electron transport layer comprises at least a first electron transport sublayer and a second electron transport sublayer having a material different from the first electron transport sublayer.

19. The organic light emitting device of claim 13, wherein the emissive layer comprises a plurality of emissive sublayers.

20. The organic light emitting device of claim 19, wherein the plurality of emissive sublayers comprise red, green, and blue sublayers.
